(19) United States
(12) Patent Application Publication
(10) Pub. No.: US 2005/0224917 A1
(43) Pub. Date: Oct. 13, 2005

(54) Junction diode

(76) Inventor: Jing-Horng Gau, Chutung Town (TW)

Correspondence Address: J C PATENTS, INC., 4 VENTURE, SUITE 250, IRVINE, CA, 92618, US

(21) Appl. No.: 10/823,244

(22) Filed: Apr. 12, 2004

(51) Int. Cl. H01L 31/072

(52) U.S. Cl. 257/598; 257/653; 257/601

(57) ABSTRACT

A junction diode comprising a first conductive type substrate, a second conductive type embedded region, a second conductive type well, a first conductive type doped region and a second conductive type doped region is provided. The second conductive type embedded region is formed within the first conductive type substrate. The second conductive type well is formed within the second conductive type embedded region. The concentration of dopants in the second conductive type well is smaller than the concentration of dopants in the second conductive type embedded region. The first conductive type doped region is formed in the second conductive type well. The second conductive type doped region is formed in the second conductive type embedded region. The junction diode has a smaller capacitance serves as an electrostatic discharge protection device for a radio frequency (RF) circuit without adversely affecting the transmission rate of the RF circuit.

### BACKGROUND OF THE INVENTION

1. Field of the Invention

The present invention relates to an electrostatic discharge protection device. More particularly, the present invention relates to a low capacitance junction diode serving as an electrostatic discharge protection circuit.

2. Description of Related Art

Electrostatic discharge is a movement of static charges from the surface of a non-conductive body to another body and hence is a major cause of damage to semiconductor devices of integrated circuits (IC) or other electrical circuits. For example, a person walking on a carpet can generate a static voltage from several hundreds to several thousand volts even if the relative humidity is high. If the relative humidity is low, a static voltage in excess of ten thousand volts may be produced. Similarly, IC packaging machines or IC testing instruments may be statically charged from several hundred to several thousand volts due to humidity or other environmental factors. When the aforementioned charged body (human body, machine or instrument) manage to contact an IC chip, an electrostatic discharge will occur leading to a transient power surge that may damage the IC chip irreparably.

To prevent the damage to an IC chip due to an electrostatic discharge, various types of electrostatic discharge (ESD) protection devices have been developed. The most common method is to set up an electrostatic discharge protection circuit in the input/output (1/O) pads of the chip so that the majority of the discharge current is redirected through a discharge pathway instead of coursing through circuits within the chip.

FIG. 1 is a circuit diagram of a conventional electrostatic discharge circuit. As shown in FIG. 1, the electrostatic discharge protection circuit 100 uses a pair of diodes 104 and 106 as a protective device for the circuit. In general, the peak voltage and the voltage valley of the input/output signal in an integrated circuit (not shown) lie close to the power source voltage V_{dd} and the ground voltage Vₛₛ. Hence, the cathode of the diode 104 and the anode of the diode 106 in the electrostatic discharge protection circuit 100 are electrically connected to the power source V_{dd} and the ground Vₛₛ. Furthermore, the electrostatic discharge protection circuit 100 also uses a MOS transistor 108 as a clamping device with connection to the power source V_{dd} and the ground Vₛₛ for maintaining a voltage differential between the power source V_{dd} and the ground Vₛₛ.

When the integrated circuit is turned on for normal operation, signals are transmitted into or out of the integrated circuit through the input/output pads 102. Since the diodes 104 and 106 are in reverse bias, both diodes 104 and 106 are non-conductive. On the other hand, when a sudden electrostatic discharge occurs leading to a large peak/valley voltage surge (2K/−2K Volts) in the integrated circuit, the diodes 104 and 106 are in the conductive state or breakdown mode. Therefore, the electrostatic discharge protection circuit 100 will redirect the discharge current to the ground or the power source terminal without going into any internal integrated circuits.

However, conventional diodes are mostly fabricated as MOS devices and hence have a higher capacitance than pure diode devices. In radio frequency (RF) integrated circuits, a higher internal capacitance often translates into a drop in transmission rate. Furthermore, a diode fabricated as a MOS device typically occupies a larger surface area, which is a major disadvantage for miniaturizing integrated circuits.

### SUMMARY OF THE INVENTION

Accordingly, the present invention is related to provide a junction diode having a smaller capacitance and occupying a smaller area that can be used as an electrostatic discharge protection circuit in a radio frequency (RF) circuit. The junction diode has very little effect on the performance of the RF circuit and can be fabricated using a conventional bipolar CMOS (BiCMOS) process.

The present invention is also related to a junction diode having a smaller capacitance and occupying a smaller area that can be used as an electrostatic discharge protection circuit in a radio frequency (RF) circuit. The junction diode has very little effect on the transmission rate of the RF circuit and can be fabricated using an additional masking step in a conventional CMOS process.

according to an embodiment of the present invention, the junction diode comprises a first conductive type substrate, a second conductive type embedded region, a second conductive type well, a first conductive type doped region and a second conductive type doped region. The second conductive type embedded region is formed within the first conductive type substrate. The second conductive type well is formed within the second conductive type embedded region. The concentration of dopants in the second conductive type well is smaller than the concentration of dopants in the second conductive type embedded region. The first conductive type doped region is formed in the second conductive type well. The second conductive type doped region is formed in the second conductive type embedded region.

According to one embodiment of the present invention, the first conductive type substrate is a P-type substrate and the second conductive type embedded region is an N-type embedded region, for example. The second conductive type well is an N-type well, for example. Preferably, the second conductive type well is an N-type epitaxial layer. The first conductive type doped region is a P-doped region and the second conductive type doped region is an N-doped region, for example. In one embodiment, the junction diode further includes an isolation structure set between the first conductive type doped region and the second conductive type doped region.

According to another embodiment of the present invention, the junction diode comprises a first conductive type substrate, a second conductive type deep well, a first conductive type well, a first conductive type shallow well, a plurality of first conductive type doped regions, a plurality of second conductive type doped region and a plurality of isolation structures. The second conductive type deep well is formed within the first conductive type substrate. The first conductive type well is formed within the second conductive type deep well. The first conductive type shallow well is formed within the first conductive type well. The concentration of dopants in the first conductive type shallow well is smaller than the concentration of dopants in the first conductive type well. The first conductive type doped region is formed in the first conductive type well. The second conductive type doped region is formed in the first conductive type shallow well and the second conductive type deep well.

According to one embodiment of the present invention, the first conductive type substrate is a P-type substrate and the second conductive type deep well is an N-type deep well, for example. The first conductive type well is a P-type well and the first conductive type shallow well is a P-type shallow well, for example. The first conductive type doped region is a P-doped region and the second conductive type doped region is an N-doped region, for example. Furthermore, each isolation structure is set between a second conductive type doped region and its neighboring first conductive type doped region.

In brief, the concentration of dopants at one end of the junction diode is smaller than the concentration of dopants at the other end of the junction diode in the present invention so that overall capacitance of the junction diode is reduced. The junction diode of the present invention can serve as an electrostatic discharge protection circuit for a radio frequency circuit without adversely affecting the transmission rate of the radio frequency circuit due to excessive capacitance.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a circuit diagram of a conventional electrostatic discharge circuit.

FIG. 2 is a schematic cross-sectional view of a junction diode according to one preferred embodiment of the present invention.

FIG. 3 is a schematic cross-sectional view of a junction diode according to another preferred embodiment of the present invention.

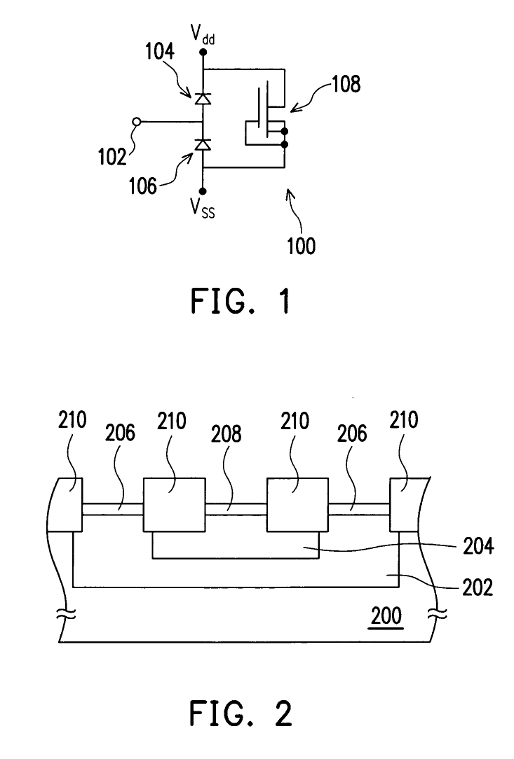

### DESCRIPTION OF THE EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

The present invention provides a junction diode with a lower capacitance to serve as an electrostatic discharge protection device in a radio frequencycircuit without adversely affecting the transmission rate of the radio frequency circuit. In the following, an embodiment of the present invention is described. However, it should not be used to limit the scope of the present invention. In particular, although the first conductive type is assumed to be a P-type and the second conductive type is assumed to be an N-type in the following embodiment, the first conductive type can be an N-type and the second conductive type can be a P-type.

FIG. 2 is a schematic cross-sectional view of a junction diode according to one preferred embodiment of the present invention. As shown in FIG. 2, the junction diode comprises a P-type substrate 200, an N-type deep well 202, an N-type well 204, a P-doped region 208, an N-doped region 206 and an isolation structure 210. The N-type deep well 202 is formed within the P-type substrate 200 and the N-type well 204 is formed within the N-type deep well 202. Furthermore, the concentration of dopants in the N-type well 204 is smaller than the concentration of dopants in the N-type deep well 202.

The P-doped region 208 is formed within the N-type well 204 and the N-doped region 206 is formed within the N-type deep well 202. The N-type deep well 202, the N-type well 204, the P-doped region 208 and the N-doped region 206 are formed, for example, by performing an ion implantation using ions set to an energy level suitable for landing at a particular depth within the P-type substrate 200.

It should be noted that an N-type deep well 202 is formed between the N-type well 204 and the P-type substrate 200 because the N-type well 204 has a lighter concentration of dopants. The N-type deep well 202 prevents current flowing into the N-type well 204 via the P-doped region 208 from directly impinging the P-type substrate 200 to cause junction diode failure due to a large depletion region in the N-type well 204.

In addition, the isolation structure 210 is set between the P-doped region 208 and the N-doped region 206 to prevent the formation of a channel between the P-doped region 208 and the N-doped region 206 and lead to junction diode failure. The isolation structure 210 is formed, for example, by performing a local oxidation process or by forming a shallow trench isolation (STI) structure.

The junction diode according to this embodiment can be fabricated using conventional bipolar complementary metal-oxide-semiconductor (BiCMOS) process. Furthermore, in most BiCMOS process, the N-type well 204 is an N-type epitaxial layer with a dopant concentration at least a grade level lower than a conventional well. Therefore, using the N-type epitaxial layer as the N-type terminal according to the present invention can produce a low capacitance junction diode.

Furthermore, the junction diode of the present invention can be fabricated using a convention CMOS process. In the following, a detailed description of this embodiment is provided.

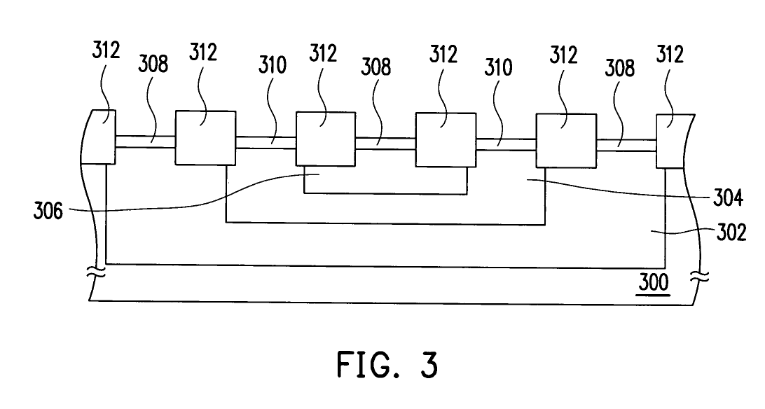

FIG. 3 is a schematic cross-sectional view of a junction diode according to another preferred embodiment of the present invention. As shown in FIG. 3, the junction diode mainly comprises a P-type substrate 300, an N-type deep well 302, a P-type well 304, a P-type shallow well 306, a P-doped region 310, an N-doped region 308 and an isolation structure 312. The N-type deep well 302 is formed within the P-type substrate 300 and the P-type well 304 is formed within the N-type deep well 302. The P-type shallow well 306 is formed within the P-type well 304. Furthermore, the concentration of dopants in the P-type shallow well 306 is smaller than the concentration of dopants in the P-type well 304.

The P-doped region 310 is formed within the P-type well 304 and the N-doped region 308 is formed within the P-type shallow well 306 and the N-type deep well 302. The N-type deep well 302, the P-type well 304, the P-type shallow well 306, the P-doped region 310 and the N-doped region 308 are formed, for example, by performing an ion implantation using ions set to an energy level suitable for landing at a particular depth within the P-type substrate 300.

It should be noted that a P-type substrate is often used as a substrate for forming devices in a CMOS process. To prevent signals entering the junction diode via the P-doped region 310 and propagating elsewhere through the P-type substrate 300 as noise, an N-type deep well 302 is formed within the P-type substrate 300 to stop any signals from reaching the P-type substrate 300.

Because the P-type shallow well 306 has a lower dopant concentration, a P-type well 304 is formed between the P-type shallow well 306 and the N-type deep well 302. The P-type well 304 prevents a current flowing from the N-doped region 308 into the P-type shallow region 306 from directly impinging the N-type deep well 302 to cause junction diode failure due to a large depletion region in the P-type shallow well 306.

In addition, an isolation structure 312 is formed between each N-doped region 310 and its neighboring P-doped region 308 to prevent the formation of a conductive channel between the P-doped region 310 and the N-doped region 308 and lead to the mal-function of the junction diode. The isolation structure 312 is formed in a similar way to the isolation structure 210 (FIG. 2) in the aforementioned embodiment.

The aforementioned junction diode structure can be fabricated using conventional CMOS process with the addition of a masking step to form the P-type well 304.

In summary, the junction diode according to the present invention can be directly fabricated using conventional BiCMOS process or using convention CMOS process with the addition of a masking step. Hence, the junction diode can be manufactured without any complicated additional steps.

Furthermore, the capacitance of the junction diode mainly depends on the concentration of dopants at the terminals and areas of the terminals. Since one of the terminals in the junction diode has a lower dopant concentration, for example, the N-type terminal in the first embodiment and the P-type terminal of the second embodiment, the junction diode has a lower capacitance. According to the experimental results, the junction diode can reach 4000V in human body discharge mode and 200V in machine discharge mode at a capacitance of about 32.1 fF compared with several hundreds fF for a conventional diode. The junction diode has such a small capacitance that it is particularly advantageous to be used as an electrostatic discharge protection device for a radio frequency circuit because excessive capacitance will reduce the transmission rate the radio frequency circuit.

When the junction diode according to the present invention is used in an electrostatic discharge protection circuit, more than two junction diodes can be serially connected to obtain an even smaller equivalent capacitance. From experiments, if two junction diodes each having a capacitance 32.fF are serially connected together, the equivalent capacitance is about 15.6 fF.

In addition, the junction diode according to the present invention occupies an area smaller than a convention MOS diode. Consequently, using the junction diode of the present invention instead of the conventional MOS diode is able to increase the level of integration of integrated circuits.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A junction diode, comprising:
a first conductive type substrate;
a second conductive type embedded region, formed within the first conductive type substrate;
a second conductive type well, formed within the second conductive type embedded region, wherein the second conductive type well has a dopant concentration smaller than the second conductive type embedded region, and the second conductive type embedded region surrounds the second conductive type well;
a first conductive type doped region, formed in the second conductive type well; and
at least two a second conductive type doped regions formed in the second conductive type embedded region beside the first conductive type dosed region.

2. The junction diode of claim 1, wherein the first conductive type substrate comprises a P-type substrate.

3. The junction diode of claim 1, wherein the second conductive type embedded region comprises an N-type embedded region.

4. The junction diode of claim 1, wherein the second conductive type well comprises an N-type well.

5. The junction diode of claim 1, wherein the second conductive type well comprises an epitaxial layer.

6. The junction diode of claim 5, wherein the epitaxial layer comprises an N-type epitaxial layer.

7. The junction diode of claim 1, wherein the first conductive type doped region comprises a P-doped region.

8. The junction diode of claim 1, wherein the second conductive type doped region comprises an N-doped region.

9. The junction diode of claim 1, wherein junction diode further comprises a plurality of isolation structures set between the first conductive type doped region and the second conductive type doped region.

10. A junction diode, comprising:
a first conductive type substrate;
a second conductive type deep well, formed within the first conductive type substrate;
a first conductive type well, formed within the second conductive type deep well;
a first conductive type shallow well, formed within the first conductive type well, wherein the first conductive type shallow well has a dopant concentration smaller than the first conductive type well;
a plurality of first conductive type doped regions, formed in the first conductive type well; and
a plurality of second conductive type doped regions formed in the first conductive type shallow well and the second conductive type deep well, wherein the second conductive type doped region formed in the first conductive type shallow well is isolated from the second conductive type deep well by the first conductive type well and the first conductive type shallow well.

11. The junction diode of claim 10, wherein the first conductive type substrate comprises a P-type substrate.

12. The junction diode of claim 10, wherein the second conductive type deep well comprises an N-type deep well.

13. The junction diode of claim 10, wherein the first conductive type well comprises a P-type well.

14. The junction diode of claim 10, wherein the first conductive type shallow well comprises a P-type shallow well.

15. The junction diode of claim 10, wherein the first conductive type doped region comprises a P-doped region.

16. The junction diode of claim 10, wherein the second conductive type doped region comprises an N-doped region.

17. The junction diode of claim 10, wherein the junction diode further comprises a plurality of isolation structures with each isolation structure set between every pair of first conductive type doped region and second conductive type doped region.
